(19) United States
(12) Patent Application Publication
(10) Pub. No.: US 2026/0362731 A1
(43) Pub. Date: Nov. 12, 2026

(54) SEMICONDUCTOR DEVICE

(71) Applicant: Mitsubishi Electric Corporation, Tokyo (JP)

(72) Inventor: Yoshiaki TANIGUCHI, Tokyo (JP)

(73) Assignee: Mitsubishi Electric Corporation, Tokyo (JP)

(21) Appl. No.: 19/113,779

(22) PCT Filed: Nov. 13, 2023
(86) PCT No.: PCT/JP2023/040741

§ 371 Date: Mar. 20, 2025

(51) Int. Cl. H10D 30/47; H10D 62/10; H10D 62/60; H10D 64/23

(52) U.S. Cl. CPC H10D 30/475; H10D 62/102; H10D 62/124; H10D 62/60; H10D 64/256

(57) ABSTRACT

A channel layer (2), a barrier layer (3), and a cap layer (4) are formed on a substrate (1) in this order. First and second contact layers (7,8) of N-type respectively formed in first and the second recesses (5,6) formed up to part of the channel layer (2) and penetrating through the cap layer (4) and the barrier layer (3). A source electrode (9) is formed on the first contact layer (7). A drain electrode (10) is formed on the second contact layer (8). A gate electrode (11) is formed on the cap layer (4) between the source electrode (9) and the drain electrode (10). A sectional shape of the first recess (5) is inverse tapered. A width of the first contact layer (7) becomes wider toward a bottom portion of the first recess (5).

### FIELD

The present disclosure relates to a semiconductor device.

### BACKGROUND

A nitride semiconductor transistor in which a recess is formed under each of a source electrode and a drain electrode, and an n-type contact layer is embedded into the recess to achieve lower resistance has been proposed (see, for example, PTL 1).

### CITATION LIST

### Patent Literature

[PTL 1] JP 2019-33155 A

### SUMMARY OF THE INVENTION

### Problem to be Solved by the Invention

In related art, a recess has a straight or forward tapered structure, leaving uniform impurity concentration of a contact layer formed in such a recess. While lower resistance can be achieved by increasing the impurity concentration of the contact layer, there is a problem that withstand voltage characteristics as a device degrade.

The present disclosure has been made to solve the problem as described above, and an object of the present disclosure is to provide a semiconductor device capable of achieving both lower resistance and improvement in withstand voltage characteristics.

### Solution to Problem

A semiconductor device according to the present disclosure includes: a substrate; a channel layer formed on the substrate; a barrier layer formed on the channel layer; a cap layer formed on the barrier layer; first and second contact layers of N-type respectively formed in first and the second recesses formed up to part of the channel layer and penetrating through the cap layer and the barrier layer; a source electrode formed on the first contact layer; a drain electrode formed on the second contact layer; and a gate electrode formed on the cap layer between the source electrode and the drain electrode, wherein a sectional shape of the first recess is inverse tapered, and a width of the first contact layer becomes wider toward a bottom portion of the first recess.

### Advantageous Effects of Invention

In the present disclosure, the n-type first contact layer is formed in the first recess having an inverse tapered sectional shape. In this case, in the first contact layer, the impurity concentration of the edge portions of the bottom portion of the first recess becomes locally higher than impurity concentration of other portions. It is therefore possible to sufficiently increase the impurity concentration of the first contact layer near the two-dimensional electron gas layer of the channel layer that contributes to electric conduction of a transistor, thereby achieving lower resistance while maintaining a withstand voltage without making the impurity concentration of the whole of the first contact layer too high. It is therefore possible to achieve lower resistance and improvement in withstand voltage characteristics.

### BRIEF DESCRIPTION OF THE DRAWINGS

FIG. 1 is a sectional view illustrating a semiconductor device according to a first embodiment.

FIG. 2 is a sectional view illustrating a semiconductor device according to a second embodiment.

FIG. 3 is a sectional view illustrating a semiconductor device according to a third embodiment.

FIG. 4 is a sectional view illustrating a semiconductor device according to a fourth embodiment.

FIG. 5 is a sectional view illustrating a semiconductor device according to a fifth embodiment.

A semiconductor device according to the embodiments of the present disclosure will be described with reference to the drawings. The same components will be denoted by the same symbols, and the repeated description thereof may be omitted.

### FIRST EMBODIMENT

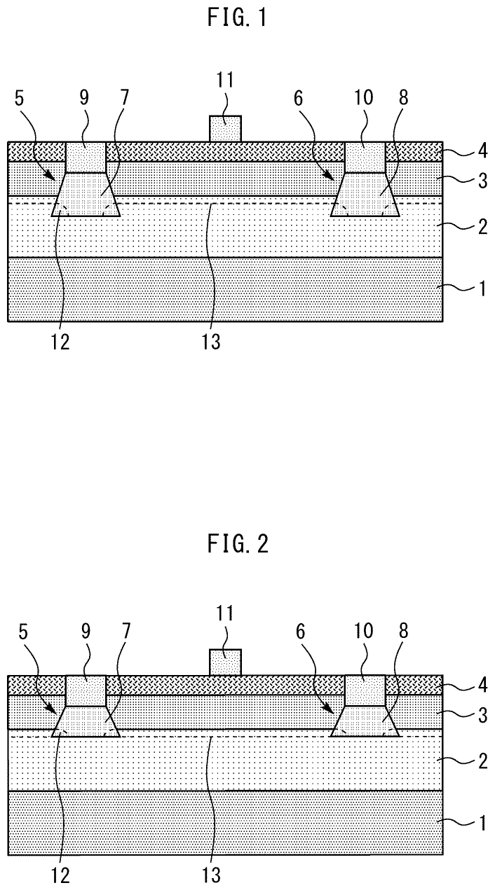

FIG. 1 is a sectional view illustrating a semiconductor device according to a first embodiment. This semiconductor device is a high electron mobility transistor (HEMT) using a nitride gallium (GaN) material.

A substrate 1 is constituted with, for example, semi-insulating SiC. A channel layer 2 is formed on the substrate 1. A barrier layer 3 is formed on the channel layer 2. A cap layer 4 is formed on the barrier layer 3. The channel layer 2 and the cap layer 4 are, for example, constituted with a non-doped GaN. The barrier layer 3 is, for example, constituted with a non-doped AlGaN.

First and second recesses 5, 6 are formed up to part of the channel layer 2 while being separated from each other and penetrating through the cap layer 4 and the barrier layer 3. The first and the second recesses 5, 6 are formed through plasma etching. When a voltage (power) of the plasma etching is increased, sectional shapes of the first and the second recesses 5, 6 become inverse tapered. Specifically, applying a voltage five times or more of that in the case of making the recesses forward tapered results in inversely tapered recesses.

N-type first and second contact layers 7, 8 are respectively formed in the first and the second recesses 5, 6. The first and the second contact layers 7, 8 are, for example, constituted with n-type GaN. An n-type dopant is, for example, Si (silicon), Ge (germanium), Te (tellurium), or the like. The first and the second contact layers 7, 8 cover a side wall of the barrier layer 3, a side wall and an upper surface of the channel layer 2 in the first and the second recesses 5, 6. A width of the first and the second recesses 5, 6 becomes wider toward bottom portions of the first and the second recesses 5, 6. A width of the first and the second contact layers 7, 8 is, for example, 1 to 100 μm. Impurity concentration of the first and the second contact layers 7, 8 is from 10¹⁵ to 10²⁰ cm⁻³.

A source electrode 9 is formed on the first contact layer 7. A drain electrode 10 is formed on the second contact layer 8. The source electrode 9 and the drain electrode 10 are respectively embedded into the first and the second recesses 5, 6. A gate electrode 11 is formed on the cap layer 4 between the source electrode 9 and the drain electrode 10.

Here, the first and the second contact layers 7, 8 are grown through chemical vapor deposition (MOCVD) and embedded into the inverse tapered first and the second recesses 5, 6. In this event, impurities are likely to accumulate at edge portions of the bottom portions of the first and the second recesses 5, 6. Thus, the first contact layer 7 has a high impurity concentration region 12 in which impurity concentration is higher than impurity concentration of other portions of the first contact layer 7, at the edge portions of the bottom portion of the first recess 5. Note that impurity concentration of a central portion of the recess bottom portion does not become high. The same applies to the second contact layer 8. A two-dimensional electron gas layer 13 of the channel layer 2 is generated near the high impurity concentration region 12.

The impurity concentration of the high impurity concentration region 12 is equal to or higher than 1×10¹⁹ cm⁻³. Note that chemically vapor-depositing the n-type semiconductor in the straight or forward tapered recess leaves a uniform impurity concentration, which makes it unable to locally form a high impurity concentration region.

As described above, in the present embodiment, the n-type first contact layer 7 is formed in the first recess 5 having an inverse tapered sectional shape. In this case, in the first contact layer 7, the impurity concentration of the edge portions of the bottom portion of the first recess 5 becomes locally higher than impurity concentration of other portions. It is therefore possible to sufficiently increase the impurity concentration of the first contact layer 7 near the two-dimensional electron gas layer 13 of the channel layer 2 that contributes to electric conduction of a transistor, thereby achieving lower resistance while maintaining a withstand voltage without making the impurity concentration of the whole of the first contact layer 7 too high. It is therefore possible to achieve lower resistance and improvement in withstand voltage characteristics.

Further, a sectional shape of the second recess 6 is also inverse tapered, and a width of the second contact layer 8 becomes wider toward a bottom portion of the second recess 6. This makes it possible to sufficiently increase impurity concentration of the second contact layer 8 near the two-dimensional electron gas layer 13 of the channel layer 2, thereby achieving lower resistance.

### Second Embodiment

FIG. 2 is a sectional view illustrating a semiconductor device according to a second embodiment. In the present embodiment, a height of the bottom portions of the first and the second recesses 5, 6 is the same as a height of the two-dimensional electron gas layer 13. The impurity concentration of the first and the second contact layers 7, 8 becomes the highest at the edge portions of the bottom portions of the first and the second recesses 5, 6. Thus, the portions at which the impurity concentration is the highest in the first and the second contact layers 7, 8 can be connected to the two-dimensional electron gas layer 13, so that it is possible to achieve lower resistance than the first embodiment. Other configurations and effects are similar to those in the first embodiment.

### Third Embodiment

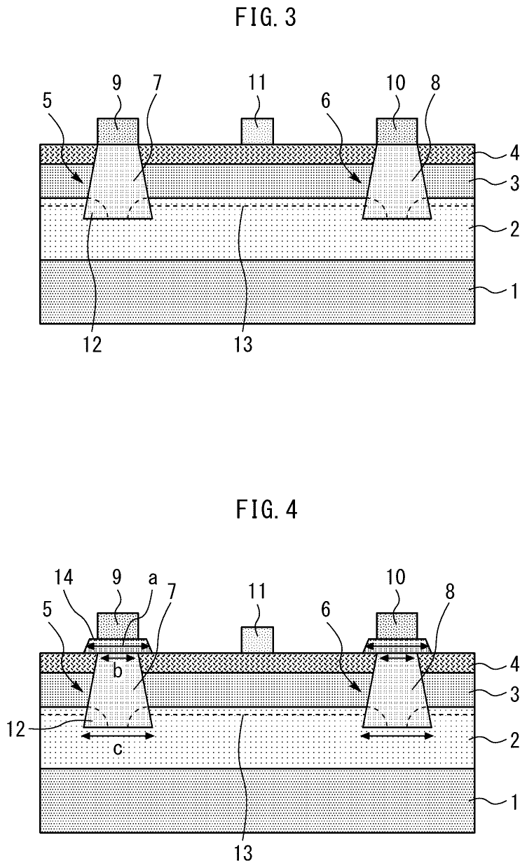

FIG. 3 is a sectional view illustrating a semiconductor device according to a third embodiment. In the present embodiment, the first and the second contact layers 7, 8 also cover a side wall of the cap layer 4 in the first and the second recesses 5, 6. This makes film thicknesses of the first and the second contact layers 7, 8 thicker than those in the first embodiment, so that a doping amount of impurities included in the first and the second contact layers 7, 8 increases. This makes it possible to prevent an increase in sheet resistance and achieve lower resistance than the first embodiment. Other configurations and effects are similar to those in the first embodiment.

### Fourth Embodiment

FIG. 4 is a sectional view illustrating a semiconductor device according to a fourth embodiment. In the present embodiment, the first and the second contact layers 7, 8 include overlap portions 14 that respectively extend outside the first and the second recesses 5, 6 and spread on the cap layer 4.

A width a of the overlap portions 14 is wider than an opening width b of the first and the second recesses 5, 6. In other words, the overlap portions 14 having a larger area than the openings of the first and the second recesses 5, 6 are formed on the cap layer 4. This makes a contact area between the first and the second contact layers 7, 8 and the source electrode 9 and the drain electrode 10 larger, so that it is possible to reduce contact resistance. However, as the width a of the overlap portions 14 becomes wider, the overlap portions 14 become closer to the gate electrode 11, which increases a leak current to the gate electrode 11. Thus, the width a of the overlap portions 14 is made smaller than a width c of the bottom portions of the first and the second recesses 5, 6.

### Fifth Embodiment

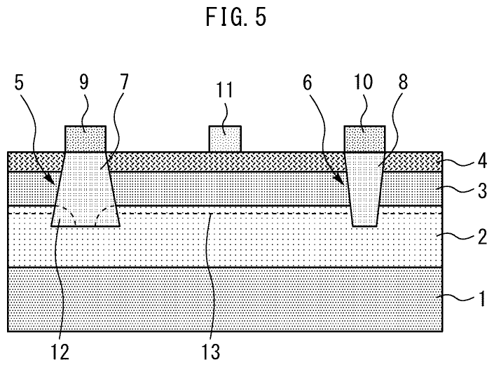

FIG. 5 is a sectional view illustrating a semiconductor device according to a fifth embodiment. In the present embodiment, the second contact layer 8 covers a side wall of the cap layer 4 in the second recess 6. The second recess 6 has a forward tapered sectional shape, and a width of the second contact layer 8 becomes narrower toward the bottom portion of the second recess 6. In a case where the second recess 6 has a forward tapered shape in this manner, an angle of a corner between the side surface of the second contact layer 8 and the upper surface of the cap layer 4 becomes obtuse. Thus, a volume of an epi structure of the cap layer 4 near the corner increases, and an electric field applied to the corner is alleviated, which increases a withstand voltage of the element.

Note that electrons flow from the source electrode 9 to the drain electrode 10 during operation of the transistor, and thus, a structure on the source electrode 9 side is dominant in achieving lower resistance of the device. Thus, in a similar manner to other embodiments, the first recess 5 on the source electrode 9 side is made inverse tapered to achieve lower resistance of the first contact layer 7. Other configurations and effects are similar to those in the third embodiment.

### REFERENCE SIGNS LIST

1 substrate; 2 channel layer; 3 barrier layer; 4 cap layer; 5 first recess; 6 second recess; 7 first contact layer; 8 second contact layer; 9 source electrode; 10 drain electrode; 11 gate electrode; 12 high impurity concentration region; 13 two-dimensional electron gas layer; 14 overlap portion

1. A semiconductor device comprising:
a substrate;
a channel layer formed on the substrate;
a barrier layer formed on the channel layer;
a cap layer formed on the barrier layer;
first and second contact layers of N-type respectively formed in first and the second recesses formed up to part of the channel layer and penetrating through the cap layer and the barrier layer;
a source electrode formed on the first contact layer;
a drain electrode formed on the second contact layer; and
a gate electrode formed on the cap layer between the source electrode and the drain electrode,
wherein a sectional shape of the first recess is inverse tapered, and
a width of the first contact layer becomes wider toward a bottom portion of the first recess.

2. The semiconductor device according to claim 1, wherein the first contact layer has a high impurity concentration region in which impurity concentration is higher than impurity concentration of other portions of the first contact layer, at an edge portion of the bottom portion of the first recess, and
a two-dimensional electron gas layer of the channel layer is generated near the high impurity concentration region.

3. The semiconductor device according to claim 2, wherein an impurity concentration of the high impurity concentration region is equal to or higher than 1×10¹⁹ cm⁻³.

4. The semiconductor device according to claim 1, wherein a height of bottom portions of the first and the second recesses is the same as a height of the two-dimensional electron gas layer.

5. The semiconductor device according to claim 1, wherein the first and the second contact layers cover a side wall of the cap layer in the first and the second recesses.

6. The semiconductor device according to claim 5, wherein the first and the second contact layers include overlap portions that respectively extend outside the first and the second recesses and spread on the cap layer.

7. The semiconductor device according to claim 6, wherein a width of the overlap portion is wider than an opening width of the first and the second recesses and is smaller than a width of the bottom portions of the first and the second recesses.

8. The semiconductor device according to claim 1, wherein a sectional shape of the second recess is inverse tapered, and a width of the second contact layer becomes wider toward a bottom portion of the second recess.

9. The semiconductor device according to claim 1, wherein the second contact layer covers a side wall of the cap layer in the second recess,
the second recess has a forward tapered sectional shape, and
a width of the second contact layer becomes narrower toward a bottom portion of the second recess.
